(19) United States
(12) Patent Application Publication
(10) Pub. No.: US 2022/0352452 A1
(43) Pub. Date: Nov. 3, 2022

(54) THERMOELECTRIC CONVERSION MODULE, HEATING/COOLING UNIT, AND TEMPERATURE CONTROL GARMENT

(71) Applicant: Panasonic Intellectual Property Management Co., Ltd., Osaka (JP)

(72) Inventors: Makiko TANAKA, Kyoto (JP); Satoshi MAESHIMA, Kyoto (JP); Shunsuke ASANO, Kyoto (JP)

(21) Appl. No.: 17/865,054

(22) Filed: Jul. 14, 2022

Related U.S. Application Data
(63) Continuation of application No. PCT/JP2021/001301, filed on Jan. 15, 2021.
(60) Provisional application No. 62/963,164, filed on Jan. 20, 2020.
(60) Provisional application No. 62/972,509, filed on Feb. 10, 2020.

(51) Int. Cl. H01L 35/32; A41D 13/005

(52) U.S. Cl. CPC H01L 35/32; A41D 13/0058

(57) ABSTRACT

A thermoelectric conversion module includes: a first substrate and a second substrate that positionally oppose each other; a thermoelectric element group that is located between the first substrate and the second substrate and is connected to the first substrate and the second substrate; a first temperature detection element that is located between the first substrate and the second substrate and is connected to the first substrate; and a second temperature detection element that is located between the first substrate and the second substrate and is connected to the second substrate.

### CROSS REFERENCE TO RELATED APPLICATIONS

This is a continuation application of PCT International Application No. PCT/JP2021/001301 filed on Jan. 15, 2021, designating the United States of America, which is based on and claims priority of U.S. Provisional Patent Application No. 62/963,164 filed on Jan. 20, 2020, and U.S. Provisional Patent Application No. 62/972,509 filed on Feb. 10, 2020, The entire disclosures of the above-identified applications, including the specifications, drawings, and claims are incorporated herein by reference in their entirety.

### FIELD

The present disclosure relates to a portable heating/cooling unit including a thermoelectric conversion module that utilizes the Peltier effect, and a temperature control garment that can house the heating/cooling unit and provide a warm or cool sensation to the user's skin surface.

### BACKGROUND

A thermoelectric conversion module that utilizes the Peltier effect is known (for example, see Patent Literature (PTL) 1). In addition, heating/cooling units are being developed that use a thermoelectric conversion module to provide a warm or cool sensation to the user's skin surface.

### CITATION LIST

### Patent Literature

PTL 1: Japanese Unexamined Patent Application Publication No. 2009-260256

### SUMMARY

### Technical Problem

When a thermoelectric conversion module is used to provide a warm or cool sensation to the user, one conceivable configuration is to measure the temperature of the thermoelectric conversion module and control the thermoelectric conversion module based on the measured temperature.

The present disclosure provides a thermoelectric conversion module and the like that can be adapted to a variety of controls.

### Solution to Problem

A thermoelectric conversion module according to one aspect of the present disclosure includes: a first substrate and a second substrate that positionally oppose each other; a thermoelectric element group that is located between the first substrate and the second substrate and is connected to the first substrate and the second substrate; a first temperature detection element that is located between the first substrate and the second substrate and is connected to the first substrate; and a second temperature detection element that is located between the first substrate and the second substrate and is connected to the second substrate.

A heating/cooling unit according to one aspect of the present disclosure includes: the thermoelectric conversion module; a heat transfer plate disposed on a surface of the second substrate opposite to a surface of the second substrate that faces the first substrate; a heat sink disposed on a surface of the first substrate opposite to a surface of the first substrate that faces the second substrate; a blower fan that blows air toward the heat sink; a control circuit board on which a control circuit that controls the thermoelectric conversion module and the blower fan is mounted; and a case that houses the thermoelectric conversion module, the heat transfer plate, the heat sink, the blower fan, and the control circuit board. The heat transfer plate is at least partially exposed to the outside of the case through an opening in the case.

A temperature control garment according to one aspect of the present disclosure includes: the heating/cooling unit; a garment body; and a first pocket that is provided in the garment body and houses the heating/cooling unit.

### Advantageous Effects

The present disclosure realizes a thermoelectric conversion module and the like that can be adapted to a variety of controls.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a plan view of the thermoelectric conversion module according to Embodiment 1.

FIG. 2 is a schematic cross-sectional view of the thermoelectric conversion module according to Embodiment 1.

FIG. 3 is an external perspective view of the heating/cooling unit according to Embodiment 1 from above.

FIG. 4 is an external perspective view of the heating/cooling unit according to Embodiment 1 from below.

FIG. 5 is a side view of the heating/cooling unit according to Embodiment 1.

FIG. 6 is a plan view of the heating/cooling unit according to Embodiment 1 from below.

FIG. 7 is a schematic cross-sectional view of the internal structure of the heating/cooling unit according to Embodiment 1.

FIG. 8 is an external view of the garment with a temperature control function according to Embodiment 1.

FIG. 9 is a block diagram illustrating the functional configuration of the heating/cooling unit according to Embodiment 1.

FIG. 10 is a flowchart of an operation example of the heating/cooling unit according to Embodiment 1.

FIG. 11 is a flowchart of a specific operation example of the heating/cooling unit according to Embodiment 1.

FIG. 12 is a flowchart of an operation example of the heating/cooling unit according to Embodiment 1 based on biometric information.

FIG. 13 is a flowchart of an operation example of the heating/cooling unit according to Embodiment 1 based on humidity.

FIG. 14 is a schematic cross-sectional view of the internal structure of the heating/cooling unit according to Variation 1 of Embodiment 1.

FIG. 15 is a schematic cross-sectional view of the internal structure of the heating/cooling unit according to Variation 2 of Embodiment 1.

FIG. 16 is a top view of the thermoelectric conversion module according to Embodiment 2.

FIG. 17 is a side view of the thermoelectric conversion module according to Embodiment 2.

FIG. 18 is a bottom view of the thermoelectric conversion module according to Embodiment 2.

FIG. 19 is a see-through view of the arrangement of the thermoelectric element group in the thermoelectric conversion module according to Embodiment 2.

FIG. 20 is an external perspective view of the heating/cooling unit according to Embodiment 2.

FIG. 21 is an exploded perspective view of the heating/cooling unit according to Embodiment 2.

FIG. 22 is an external perspective view of the heating/cooling unit according to Variation 1 of Embodiment 2.

FIG. 23 is an external perspective view of the heating/cooling unit according to Variation 2 of Embodiment 2.

### DESCRIPTION OF EMBODIMENTS

### Underlying Knowledge Forming the Basis of the Present Disclosure

Heating/cooling units are being developed that use a thermoelectric conversion module, which utilizes the Peltier effect, to provide a warm or cool sensation to the user's body surface (skin surface). Such a heating/cooling unit makes it possible to pursue a state in which the user is thermally comfortable. The heating/cooling unit may also contribute to the user's beauty, or may have the effect of promoting healing of the user's wounds, etc.

When the heating/cooling unit provides a cool sensation to the user, the temperature on the heat-dissipating side of the thermoelectric conversion module increases. The heating/cooling unit therefore includes a heat sink for heat dissipation and a blower fan for heat dissipation to diffuse the heat.

In the development of heating/cooling units, the need to improve the cooling effect and the need to improve the duration of comfort has led to the consideration of larger thermoelectric conversion modules and larger capacity batteries for the heating/cooling units. However, larger thermoelectric conversion modules, larger heat sinks, and larger batteries result in larger heating/cooling units that are not as portable as they could be.

In the thermoelectric module described in PTL 1, a temperature detection element is provided on only one of the two substrates included in the thermoelectric module. Such a configuration is not suitable for applications that require temperature detection or temperature control of each of the two substrates. Stated differently, adaptability to a variety of controls is a challenge.

The present disclosure describes a thermoelectric conversion module, a heating/cooling unit, and a temperature control garment that the inventors have discovered in light of these issues.

Hereinafter embodiments of the present disclosure will be described with reference to the figures. The following embodiments each describe a general or specific example. The numerical values, shapes, materials, elements, the arrangement and connection of the elements, steps, order of the steps, etc., shown in the following embodiments are mere examples, and therefore do not limit the scope of the present disclosure. Accordingly, among elements in the following exemplary embodiments, those not recited in any one of the independent claims are described as optional elements.

Note that the figures are schematic drawings, and are not necessarily exact depictions. Additionally, in the figures, elements that are essentially the same share like reference signs. Accordingly, repeated description may be omitted or simplified.

Coordinate axes may be indicated in the figures referenced in the following embodiments. The Z-axis direction among the coordinate axes is, for example, the vertical direction. The Z-axis positive direction side is expressed as the upper side (upward/above), and the Z-axis negative direction side is expressed as the lower side (downward/below). Stated differently, the Z-axis direction is perpendicular to the main surfaces of the first substrate and the second substrate, and corresponds to the thickness direction of the first substrate and the second substrate.

The X-axis direction and the Y-axis direction are orthogonal to each other in a plane perpendicular to the Z-axis direction. The X-axis direction may be expressed as the crosswise direction or the second direction, and the Y-axis direction may be expressed as the lengthwise direction or the first direction. In the following embodiments, “plan view” refers to a view from the Z-axis direction.

### Embodiment 1

### Configuration of Thermoelectric Conversion Module

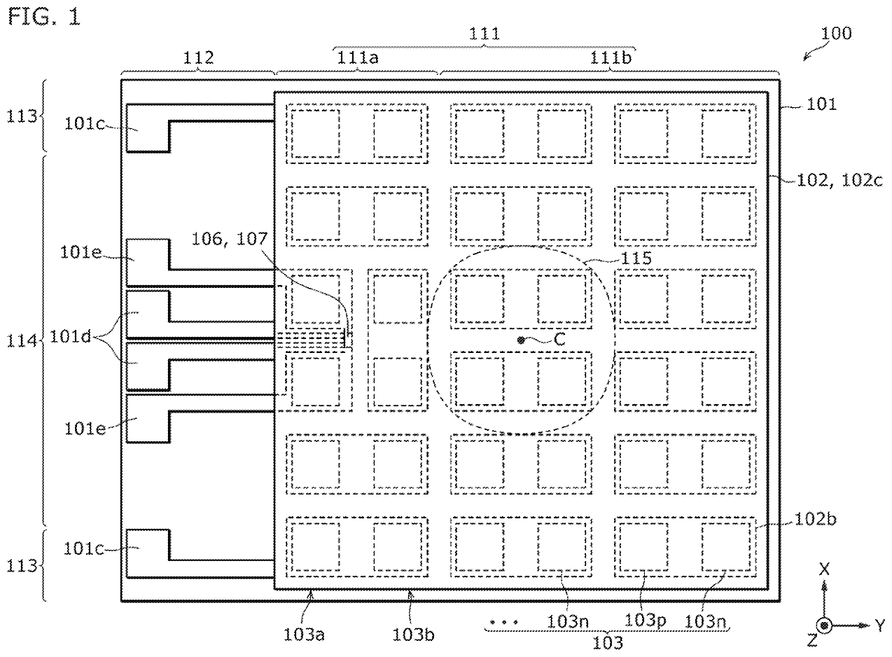

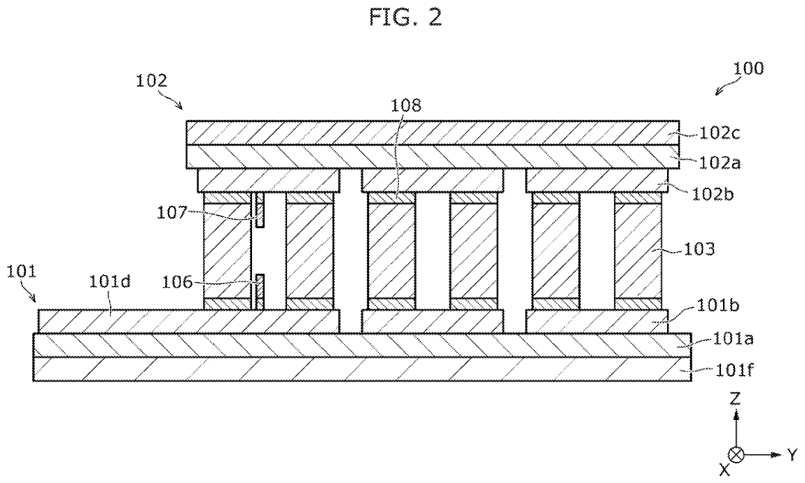

Hereinafter, the configuration of the thermoelectric conversion module according to Embodiment 1 will be described with reference to the drawings. FIG. 1 is a plan view of the thermoelectric conversion module according to Embodiment 1. FIG. 2 is a schematic cross-sectional view of the thermoelectric conversion module according to Embodiment 1. FIG. 2 illustrates a cross-section of thermoelectric conversion module 100 divided equally into two parts along the Y-axis direction in the plan view of FIG. 1.

Thermoelectric conversion module 100 according to Embodiment 1 is a thermoelectric conversion module used in a heating/cooling unit to be described later. A heating/cooling unit is a device that is housed in a pocket of a garment and provides a warm or cool sensation (in other words, a warm or cool stimulus) to the body surface of the user wearing the garment. Thermoelectric conversion module 100 includes first substrate 101, second substrate 102, thermoelectric element group 103, first temperature detection element 106, and second temperature detection element 107. Thermoelectric element group 103 includes a plurality of first thermoelectric elements 103n and a plurality of second thermoelectric elements 103p.

First substrate 101 is a component having a rectangular flat-plate plan view shape. First substrate 101 is, for example, a flexible substrate, and includes base material 101a, a plurality of pads 101b, a pair of power supply pads 101c, a pair of first pads 101d, a pair of second pads 101e, and heat dissipation pad 101f. Base material 101a is made of a flexible and electrically insulating material. Base material 101a is made of, for example, a polyimide resin material or an aramid resin material. Polyimide resin material or aramid resin material is a resin material with excellent heat resistance and strength even when thin. Although a ceramic substrate may be used as first substrate 101, a thin and strong flexible substrate is used as first substrate 101 to improve heat transfer from thermoelectric element group 103 to heat dissipation pad 101f.

The plurality of pads 101b, the pair of power supply pads 101c, the pair of first pads 101d, and the pair of second pads 101e are metal films provided on the upper surface of base material 101a. The plurality of pads 101b, the pair of power supply pads 101c, the pair of first pads 101d, and the pair of second pads 101e are made of copper, for example, but may be made of other metal materials. The plurality of pads 101b, the pair of power supply pads 101c, the pair of first pads 101d, and the pair of second pads 101e may be plated. The plurality of pads 101b, the pair of power supply pads 101c, the pair of first pads 101d, and the pair of second pads 101e have, for example, a rectangular plan view shape.

The plurality of pads 101b are metal films for connecting thermoelectric element group 103 to first substrate 101. The plurality of pads 101b are provided such that one pad 101b is provided per pair of one first thermoelectric element 103n and one second thermoelectric element 103p.

The pair of power supply pads 101c are pads for supplying power to thermoelectric element group 103, and are electrically connected to two of the plurality of pads 101b by a line-shaped metal film on the upper surface of base material 101a. As described below, when power is supplied to the pair of power supply pads 101c so that current flows in a first direction, the temperature of heat transfer pad 102c decreases and the temperature of heat dissipation pad 101f increases as a result of heat transferring from heat transfer pad 102c to heat dissipation pad 101f due to the Peltier effect. In contrast, when power is supplied to the pair of power supply pads 101c so that current flows in a second direction opposite the first direction, the temperature of heat dissipation pad 101f decreases and the temperature of heat transfer pad 102c increases as a result of heat transferring from heat dissipation pad 101f to heat transfer pad 102c due to the Peltier effect. In other words, thermoelectric conversion module 100 can change the temperature of heat transfer pad 102c by changing the direction of the current from the power supply.

The pair of first pads 101d are pads for monitoring the voltage at both ends of first temperature detection element 106, in other words, for measuring the temperature of first substrate 101 through first temperature detection element 106. The pair of first pads 101d are electrically connected to two dedicated pads for first temperature detection element 106 by a line-shaped metal film on the upper surface of base material 101a. The pair of first pads 101d are located between the pair of power supply pads 101c in the X-axis direction.

The pair of second pads 101e are pads for monitoring the voltage at both ends of second temperature detection element 107, in other words, for measuring the temperature of second substrate 102 through second temperature detection element 107. The pair of second pads 101e are electrically connected to two of the plurality of pads 101b by a line-shaped metal film on the upper surface of base material 101a. The pair of second pads 101e are located between the pair of power supply pads 101c in the X-axis direction.

Heat dissipation pad 101f is a metal film on the lower surface of base material 101a (i.e., the surface of first substrate 101 opposite to the surface facing second substrate 102). Heat dissipation pad 101f is a metal film for dissipating heat from thermoelectric conversion module 100 and is thermally connected to a heat dissipation component included in the heating/cooling device. Heat dissipation pad 101f is made of copper, for example, but may be made of other metal materials. Heat dissipation pad 101f may be plated.

Second substrate 102 is a component having a rectangular flat-plate plan view shape. Second substrate 102 is, for example, a flexible substrate, and includes base material 102a, a plurality of pads 102b, and heat transfer pad 102c. Base material 102a is made of a flexible and electrically insulating material. Base material 102a is made of, for example, a polyimide resin material or an aramid resin material. Although a ceramic substrate may be used as second substrate 102, a flexible substrate is used as second substrate 102 to improve heat transfer from thermoelectric element group 103 to heat transfer pad 102c.

The plurality of pads 102b are metal films on the lower surface of base material 102a, and are for connecting thermoelectric element group 103 to second substrate 102. The plurality of pads 102b are provided such that one pad 102b is provided per pair of one first thermoelectric element 103n and one second thermoelectric element 103p. The plurality of pads 102b are made of copper, for example, but may be made of other metal materials. The plurality of pads 102b may be plated. The plurality of pads 102b have, for example, a rectangular plan view shape.

Heat transfer pad 102c is a metal film on the upper surface of base material 102a (i.e., the surface of second substrate 102 opposite to the surface facing first substrate 101). Heat transfer pad 102c is a metal film for transferring heat from thermoelectric conversion module 100 to the user and is thermally connected to a heat transfer plate included in the heating/cooling unit. Heat transfer pad 102c is made of copper, for example, but may be made of other metal materials. Heat transfer pad 102c may be plated. Heat transfer pad 102c has, for example, a rectangular plan view shape. Heat transfer pad 102c is smaller than heat dissipation pad 101f in both the X-axis direction and the Y-axis direction in plan view.

Thermoelectric element group 103 is a group of thermoelectric elements capable of exchanging heat and power using the Seebeck effect. In FIG. 1 and FIG. 2, each thermoelectric element in thermoelectric element group 103 is illustrated as a cuboid element. Thermoelectric element group 103 includes first thermoelectric elements 103n and second thermoelectric elements 103p.

First thermoelectric element 103n is an N-type semiconductor element made of a bismuth telluride (Bi—Te) compound, and is one example of the first semiconductor element. Second thermoelectric element 103p is a P-type semiconductor element made of a bismuth telluride compound, and is one example of the second semiconductor element. The semiconductor element material that first thermoelectric elements 103n and second thermoelectric elements 103p are made of may be a material other than a bismuth telluride compound, such as an iron silicon compound or a cobalt antimony compound.

One end of first thermoelectric element 103n and one end of second thermoelectric element 103p are electrically and structurally connected to pad 101b on first substrate 101 by solder 108. The other end of first thermoelectric element 103n and the other end of second thermoelectric element 103p are electrically and structurally connected to pad 102b on second substrate 102 by solder 108.

In thermoelectric conversion module 100, thermoelectric element group 103 (i.e., the plurality of first thermoelectric elements 103n and the plurality of second thermoelectric elements 103p) are arranged in a matrix. In the matrix arrangement, first thermoelectric elements 103n and second thermoelectric elements 103p are arranged alternately. Although not shown in detail, thermoelectric element group 103 is electrically connected in series by the plurality of pads 101b and the plurality of pads 102b. The number and arrangement of first thermoelectric elements 103n and second thermoelectric elements 103p in thermoelectric element group 103 can be discretionarily determined according to, for example, the required characteristics for the thermoelectric conversion module.

First temperature detection element 106 is an element for measuring the temperature around first substrate 101. First temperature detection element 106 is located between first substrate 101 and second substrate 102 in the Z-axis direction and is connected to the upper surface of first substrate 101 by solder 108. More specifically, first temperature detection element 106 is a surface-mount type NTC thermistor, but may be a platinum resistance thermometer or the like. The temperature measured by first temperature detection element 106 is considered to be the temperature of heat dissipation pad 101f, for example. Each of both ends of first temperature detection element 106 is electrically connected to pad 101b on first substrate 101 by solder 108. The resistance values (i.e., temperature measurements) at both ends of first temperature detection element 106 can be obtained using the pair of first pads 101d.

Second temperature detection element 107 is an element for measuring the temperature around second substrate 102. Second temperature detection element 107 is located between first substrate 101 and second substrate 102 in the Z-axis direction and is connected to the lower surface of second substrate 102 by solder 108. More specifically, second temperature detection element 107 is a surface-mount type NTC thermistor, but may be a platinum resistance thermometer or the like. The temperature measured by second temperature detection element 107 is considered to be the temperature of heat transfer pad 102c, for example. Each of both ends of second temperature detection element 107 is electrically connected to a dedicated pad on second substrate 102 by solder 108. The resistance values (i.e., temperature measurements) at both ends of second temperature detection element 107 can be obtained using the pair of second pads 101e.

As described above, thermoelectric conversion module 100 includes a temperature detection element connected to first substrate 101 and a temperature detection element connected to second substrate 102. This allows thermoelectric conversion module 100 to be more adaptable to a variety of controls than a thermoelectric conversion module with only one temperature detection element. For example, thermoelectric conversion module 100 can be easily adapted to applications that require temperature detection or temperature control of each of first substrate 101 and second substrate 102.

### Arrangement of Temperature Detection Elements

Next, the arrangement of first temperature detection element 106 and second temperature detection element 107 will be described with reference to FIG. 1. Here, first substrate 101 is virtually divided into first region 111 and second region 112 for illustrative purposes. First region 111 and second region 112 are regions resulting from dividing first substrate 101 into two parts along a straight line parallel to the X-axis. First region 111 is a region that overlaps second substrate 102 in plan view, and second region 112 is a region adjacent to first region 111 that does not overlap second substrate 102 in plan view. The pads for electrically connecting thermoelectric conversion module 100 to an external circuit is provided in second region 112.

If first region 111 is further divided into two sub-regions, sub-region 111a and sub-region 111b, where sub-region 111a is located closer to second region 112 than sub-region 111b is, in plan view of thermoelectric conversion module 100, first temperature detection element 106 and second temperature detection element 107 are located in sub-region 111a of first region 111 that is closer to second region 112. Although sub-region 111a is exemplified as corresponding to two element columns in FIG. 1, it is sufficient if sub-region 111a is the sub-region closer to second region 112 when first region 111 is divided equally into two sub-regions along a straight line extending in the X-axis direction.

This shortens the distance from first temperature detection element 106 to the pair of first pads 101d, whereby the wiring connecting first temperature detection element 106 to the pair of first pads 101d can be shortened and the wiring routing can be simplified. Moreover, the wiring connecting second temperature detection element 107 and the pair of second pads 101e can be shortened and the wiring routing can be simplified.

In thermoelectric conversion module 100, first temperature detection element 106 and second temperature detection element 107 are located offset toward second region 112 within sub-region 111a as well. As illustrated in FIG. 1, first thermoelectric element column 103a and second thermoelectric element column 103b are located in sub-region 111a. First thermoelectric element column 103a is an element column that includes a portion of the thermoelectric elements in thermoelectric element group 103 and is aligned along the X-axis direction (an example of the second direction), and is the element column located closest to second region 112. Second thermoelectric element column 103b is an element column that includes a portion of the other thermoelectric elements in thermoelectric element group 103 and is aligned along the X-axis direction, and is the element column located adjacent to first thermoelectric element column 103a in the Y-axis direction. The Y-axis direction can also be expressed as the direction in which first region 111 and second region 112 are aligned (an example of the first direction).

Here, first temperature detection element 106 and second temperature detection element 107 are located closer to second region 112 than second thermoelectric element column 103b is. With this, the wiring connecting first temperature detection element 106 and the pair of first pads 101d can be further shortened and the wiring routing can be further simplified. Moreover; the wiring connecting second temperature detection element 107 and the pair of second pads 101e can be further shortened and the wiring routing can be further simplified.

Next, first substrate 101 is virtually divided into third region 113 and fourth region 114 for illustrative purposes. Third region 113 and fourth region 114 are regions resulting from dividing first substrate 101 along a straight line parallel to the Y-axis, and are adjacent to each other in the X-axis direction. Third region 113 is the region where the pair of power supply pads are provided. Fourth region 114 is adjacent to third region 113 in the X-axis direction and is the region where the pair of first pads 101d and the pair of second pads 101e are provided. When divided in this way, first temperature detection element 106 and second temperature detection element 107 are located in fourth region 114 in plan view.

With this, the wiring connecting first temperature detection element 106 and the pair of first pads 101d can be shortened and the wiring routing can be simplified. Moreover, the wiring connecting second temperature detection element 107 and the pair of second pads 101e can be shortened and the wiring routing can be simplified.

In thermoelectric conversion module 100, the above arrangement is adopted from the viewpoint of wiring routing, but from the viewpoint of temperature measurement accuracy, first temperature detection element 106 and second temperature detection element 107 should be located at central part 115 of second substrate 102 in plan view. Here, central part 115 is, for example, a circular region centered on intersection point C of the diagonals of second substrate 102, and the region the vicinity of intersection point C. Central part 115 may be defined as the center region when second substrate 102 is divided into nine equal 3×3 regions in plan view.

If first temperature detection element 106 and second temperature detection element 107 are located in central part 115, the accuracy of the temperature measurement of heat dissipation pad 101f and heat transfer pad 102c improves.

Next, the relative positions of first temperature detection element 106 and second temperature detection element 107 will be explained. As illustrated in FIG. 1, in thermoelectric conversion module 100, the silhouettes of first temperature detection element 106 and second temperature detection element 107 are aligned in plan view. This reduces the difference in temperature measurement conditions between first temperature detection element 106 and second temperature detection element 107. Note that the silhouette of first temperature detection element 106 does not need to be aligned with the silhouette of second temperature detection element 107; it is sufficient if first temperature detection element 106 overlaps second temperature detection element 107 at least partially in plan view.

When the space between first substrate 101 and second substrate 102 in the Z-axis direction is narrow, first temperature detection element 106 and second temperature detection element 107 may interfere with each other if at least part of first temperature detection element 106 overlaps second temperature detection element 107 in plan view. In such cases, first temperature detection element 106 does not need to overlap second temperature detection element 107 in plan view. This makes it difficult for first substrate 101 and second substrate 102 to interfere with each other in the Z-axis direction, thereby increasing the degree of freedom in the arrangement of first temperature detection element 106 and second temperature detection element 107.

Even if first temperature detection element 106 does not overlap second temperature detection element 107, if the space between first temperature detection element 106 and second temperature detection element 107 in plan view is narrow, the difference in temperature measurement conditions between first temperature detection element 106 and second temperature detection element 107 can be reduced. For example, the distance between first temperature detection element 106 and second temperature detection element 107 in plan view may be less than or equal to the maximum width of first temperature detection element 106 or the maximum width of second temperature detection element 107. If the plan view shape of first temperature detection element 106 and second temperature detection element 107 is a rectangle, the maximum width corresponds to the length of the short side of the rectangle.

The arrangement of first temperature detection element 106 and second temperature detection element 107 described above is merely one example; first temperature detection element 106 and second temperature detection element 107 may be arranged in any manner. For example, if the measurement accuracy of the temperature of heat transfer pad 102c is given priority over that of heat dissipation pad 101f, second temperature detection element 107 may be located closer to intersection point C of the diagonals of second substrate 102 than first temperature detection element 106 is in plan view.

### Configuration of Heating/Cooling Unit

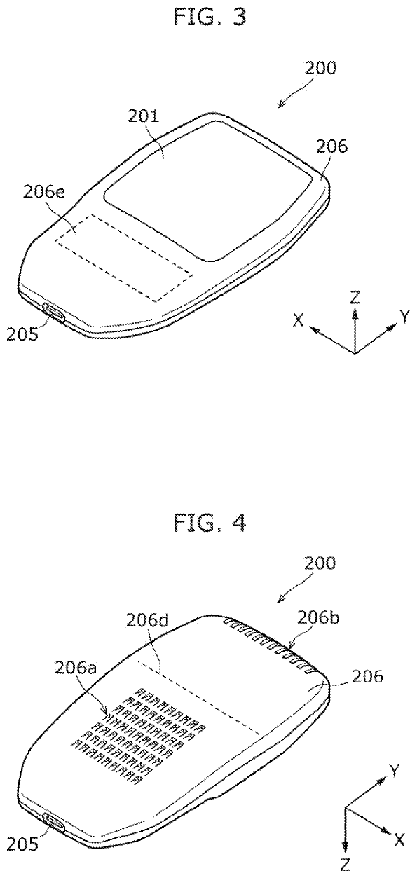

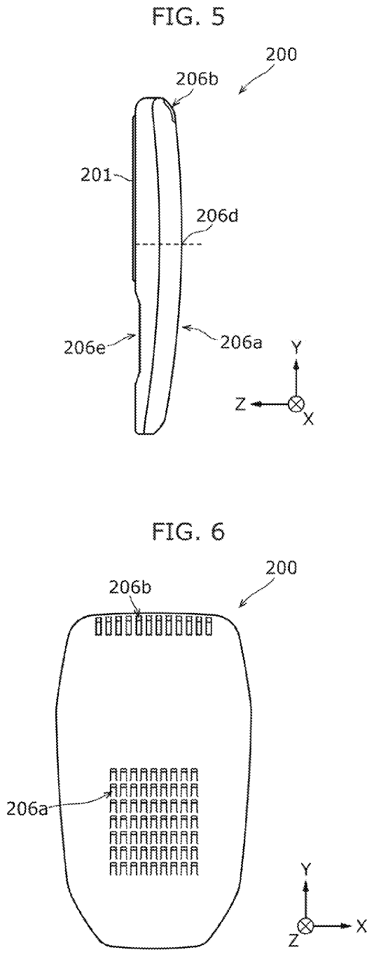

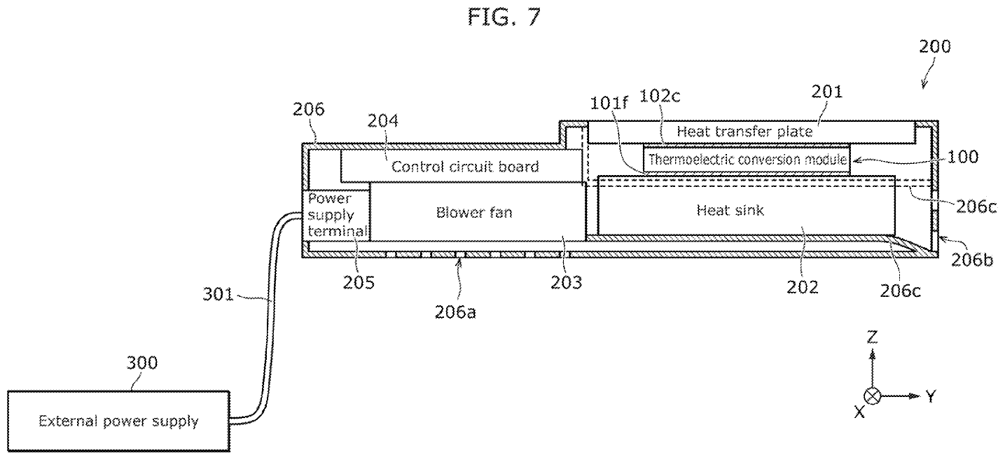

Next, the configuration of the heating/cooling unit according to Embodiment 1 will be described. FIG. 3 is an external perspective view of the heating/cooling unit according to Embodiment 1 from above. FIG. 4 is an external perspective view of the heating/cooling unit according to Embodiment 1 from below. FIG. 5 is a side view of the heating/cooling unit according to Embodiment 1, and FIG. 6 is a plan view of the heating/cooling unit according to Embodiment 1 from below. FIG. 7 is a schematic cross-sectional view of the internal structure of the heating/cooling unit according to Embodiment 1.

Heating/cooling unit 200 is a device that is housed in a pocket of a garment and provides a warm or cool sensation to the user wearing the garment. The weight of heating/cooling unit 200 is, for example, between 55 grams and 65 grams, inclusive. As illustrated in FIG. 2 through FIG. 7 (FIG. 7 in particular), heating/cooling unit 200 according to Embodiment 1 includes thermoelectric conversion module 100, heat transfer plate 201, heat sink 202, blower fan 203, control circuit board 204, power supply terminal 205, and case 206. FIG. 7 also illustrates external power supply 300. Heating/cooling unit 200 may include external power supply 300.

Heat transfer plate 201 is a plate-shaped component that positionally opposes heat transfer pad 102c of thermoelectric conversion module 100 and is thermally connected to heat transfer pad 102c. Although a high heat-dissipation grease or adhesive, for example, is interposed between heat transfer plate 201 and heat transfer pad 102c, heat transfer plate 201 and heat transfer pad 102c may be in direct contact with each other. Heating/cooling unit 200 is housed in a pocket of a garment so that heat transfer plate 201 faces toward the user's body surface, whereby the user gets a warm or cool sensation via heat transfer plate 201.

Heat transfer plate 201 is made of, for example, aluminum, but may be made of a metal with good thermal conductivity other than aluminum (for example, copper). Heat transfer plate 201 may be given a corrosion treatment, such as anodizing. The corrosion treatment inhibits corrosion of heat transfer plate 201 from contact with the user's body surface.

Heat sink 202 is a plate-shaped component that positionally opposes heat dissipation pad 101f of thermoelectric conversion module 100 and is thermally connected to heat dissipation pad 101f. Although a high heat-dissipation grease or adhesive, for example, is interposed between heat sink 202 and heat dissipation pad 101f, heat sink 202 and heat dissipation pad 101f may be in direct contact with each other. When heat transfer plate 201 cools the user's body surface in heating/cooling unit 200, heat transfer pad 102c is cooled whereas heat dissipation pad 101f is heated. Heat sink 202 is a component mainly used to dissipate heat from thermoelectric conversion module 100 when heat transfer plate 201 cools the user's body surface.

Heat sink 202 is made of a metal with good thermal conductivity, such as aluminum or copper. Although not illustrated, heat dissipation fins are provided spaced at a relatively narrow pitch on the lower surface of heat sink 202 (the surface of heat sink 202 opposite to the surface facing heat dissipation pad 101f). In plan view, heat sink 202 is larger than the thermoelectric conversion module in both the X-axis and Y-axis directions. Exhaust port 206b is provided in the portion of case 206 that is located to the side of (specifically, on the Y-axis positive direction side of) thermoelectric conversion module 100 or heat sink 202.

Blower fan 203 is an air blowing device including a motor and blades whose axis of rotation is the shaft of the motor. Blower fan 203 is secured to the inner wall of case 206 with screws or adhesive. Blower fan 203 is positioned alongside heat sink 202 in the Y-axis direction. More specifically, blower fan 203 is positioned on the Y axis negative direction side of heat sink 202.

Intake port 206a is provided in the portion of case 206 that is located on the Z-axis negative direction side of blower fan 203, i.e., in the portion that opposes blower fan 203. Blower fan 203 generates airflow from intake port 206a to exhaust port 206b. Since this airflow passes the area around the heat dissipation fins on heat sink 202, heat from heat sink 202 (heat dissipation fins) can be discharged to the outside of case 206.

The inner wall of case 206 includes guide structure 206c (for example, ribs) that guides the airflow generated by blower fan 203 to heat sink 202 and exhaust port 206b. Since guide structure 206c inhibits the outside air drawn in from intake port 206a from going around to the thermoelectric conversion module 100 side, the outside air can be efficiently used for heat dissipation of heat sink 202. Stated differently, guide structure 206c makes it possible to efficiently adjust the temperature of heat transfer plate 201.

Blower fan 203 blows air mainly toward heat sink 202, but also discharges heat generated by control circuit board 204 out of case 206 by directing the heat generated by control circuit board 204 to exhaust port 206b.

Control circuit board 204 is a circuit board on which the control circuit that controls thermoelectric conversion module 100 and blower fan 203 using power supplied via power supply terminal 205 is mounted. For example, control circuit board 204 is located on the Y-axis negative direction side of thermoelectric conversion module 100 and is electrically connected to the pair of power supply pads 101c, the pair of first pads 101d, and the pair of second pads 101e of thermoelectric conversion module 100. Lead lines may be used for electrical connection between control circuit board 204 and thermoelectric conversion module 100, and, alternatively, a flexible board may be used. Control circuit board 204 includes a board body and electronic components mounted on the board body. Electronic components include IC chips, resistor elements, capacitors, and coil elements. The functional configuration of the control circuit mounted on control circuit board 204 is described below.

Power supply terminal 205 supplies DC power supplied from external power supply 300 to, for example, control circuit board 204. External power supply 300 is connected to power supply terminal 205 via power cable 301. External power supply 300 is, for example, a general-purpose mobile battery including a secondary cell such as a lithium-ion cell. Power supply terminal 205 is, for example, a terminal compliant with the USB standard. The weight of heating/cooling unit 200 is reduced by not incorporating therein a secondary cell or other power supply. Moreover, when a power supply is built in, the storage capacity may be limited by dimensional constraints and other factors. When external power supply 300 is used, dimensional constraints are looser. Therefore, by connecting heating/cooling unit 200 to external power supply 300 having a somewhat larger storage capacity, heating/cooling unit 200 can be operated for a longer period of time.

Case 206 is a hollow component that houses thermoelectric conversion module 100, heat transfer plate 201, heat sink 202, blower fan 203, control circuit board 204, and power supply terminal 205. Case 206 is made of, for example, a plastic resin material, but may also be made of a lightweight metal material such as aluminum.

Thermoelectric conversion module 100 is housed in case 206 with at least the vicinity of heat transfer pad 102c surrounded by insulation, for example. This inhibits the heat generated by heat dissipation pad 101f from going around heat transfer pad 102c and causing the temperature of heat transfer plate 201 to rise. The height of thermoelectric element group 103 can also be increased to inhibit the heat from heat dissipation pad 101f going around heat transfer pad 102c.

The specific shape of case 206 will be described below with reference to FIG. 3 through FIG. 6. An opening is provided in the upper part (the Z-axis positive direction side) of case 206 to expose heat transfer plate 201 to the outside. Intake port 206a is conversely provided in the lower part (the Z-axis negative direction side) of case 206, so as to oppose blower fan 203. An opening is provided on the Y-axis negative direction side portion of case 206 for power supply terminal 205, and exhaust port 206b is provided on the lower portion (the portion in the Z-axis negative direction, i.e., the portion opposite to the portion on the heat transfer plate 201 side) of the end on the Y-axis positive direction side of case 206.

As illustrated in FIG. 4 and FIG. 5, the lower surface of case 206 has a gentle curvature that protrudes toward the outside of case 206, and intake port 206a is provided in an area slightly away from peak portion 206d of the curvature. When heating/cooling unit 200 is housed in a pocket of a garment, this allows space for air intake between heating/cooling unit 200 and the garment. Stated differently, it is possible to inhibit the fabric of the garment from completely covering intake port 206a. The axis of the opening of (in other words, the axis of the hole) defined by intake port 206a is inclined rather than perpendicular to the lower surface. This also allows space for air intake between heating/cooling unit 200 and the garment. If the axis of the opening defined by intake port 206a is inclined with respect to the lower surface, it will have the effect of inhibiting foreign objects such as hair, dust, or garment fibers from entering case 206 through intake port 206a.

More specifically, intake port 206a is inclined with respect to the lower surface so that the interior of case 206 can be seen from the Y-axis negative direction (the power supply terminal 205 side) and cannot be seen from the Y-axis positive direction (the exhaust port 206b side). This produces a smooth airflow from intake port 206a to exhaust port 206b.

As illustrated in FIG. 3 and FIG. 5, the portion of the upper surface of case 206 that is located to the side of heat transfer plate 201 and opposes control circuit board 204 (in other words, the portion adjacent to heat transfer plate 201) is recessed portion 206e that is recessed toward the inside of case 206 more so than heat transfer plate 201. As described above, heat transfer plate 201 is located on the side that faces the user's body surface, but the portion that opposes control circuit board 204 may be heated by the heat of control circuit board 204, and the user may feel this heat when this portion is close to or contacts the user's body surface. So long as the portion that opposes control circuit board 204 is a recessed portion, this portion is inhibited from coming close to or contacting the user's body surface. Stated differently, when recessed portion 206e is provided, heating/cooling unit 200 is inhibited from providing a warming sensation to the user that is not by design.

As illustrated in FIG. 6, exhaust port 206b is located on the lower portion (the portion in the Z-axis negative direction) of the end on the Y-axis positive direction side of case 206. As described above, in heating/cooling unit 200, the upper surface side of case 206 is positioned near the user's body surface, but exhaust port 206b is provided on the lower surface side to inhibit the hot air discharged from exhaust port 206b from hitting the user's body surface. For example, if heating/cooling unit 200 is placed behind the user's neck, the hot air discharged from exhaust port 206b can be inhibited from hitting the back of the user's head. Stated differently, by arranging exhaust port 206b as described above, heating/cooling unit 200 is inhibited from providing a warming sensation to the user that is not by design. From 10 cm to 20 cm away from exhaust port 206b, the temperature of the heated air will decrease as it mixes with the surrounding air. It is therefore unlikely to be a nuisance to other people around the user.

The silhouette of case 206, as illustrated in FIG. 6, has a longitudinal direction and a lateral direction in plan view. More specifically, the silhouette of case 206 is a rounded octagon where the Y-axis direction corresponds to the longitudinal direction and the X-axis direction corresponds to the lateral direction, and has line symmetry with respect to a line parallel to the Y-axis. Power supply terminal 205 and exhaust port 206b are located on opposite sides of the octagon. Among these opposite sides, the side corresponding to power supply terminal 205 is shorter than the side corresponding to exhaust port 206b. Stated differently, overall, the octagon can be said to have a tapered shape at the ends in the longitudinal direction of case 206, with the power supply terminal 205 side narrowed down. Heating/cooling unit 200 thus has a shape that makes it easy to place in a garment pocket from the power supply terminal 205 side.

### Temperature Control Garment

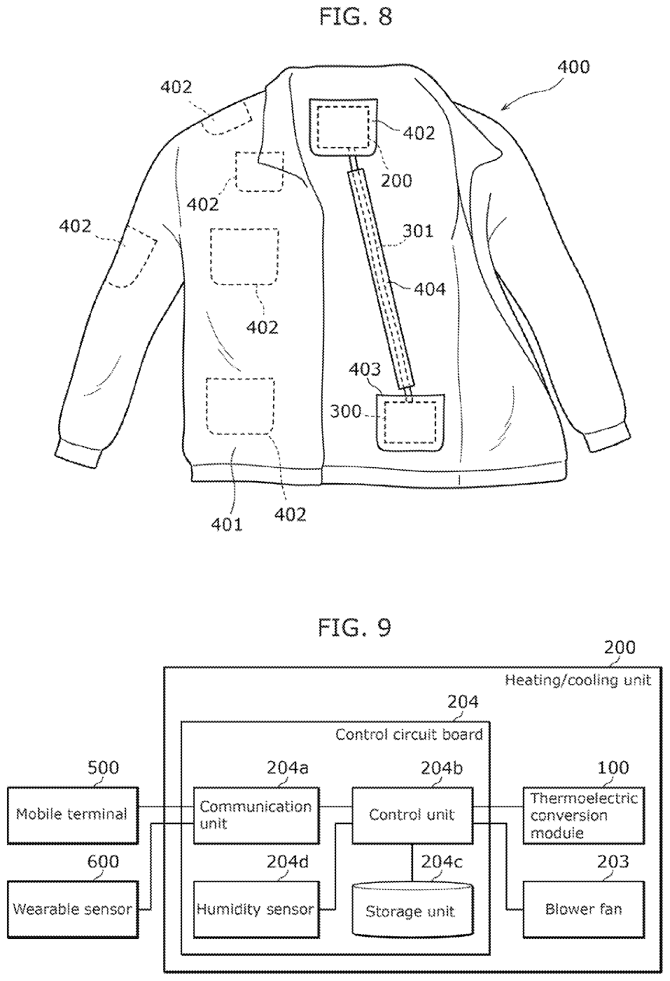

Next, the configuration of the temperature control garment (a garment with a temperature control function) according to Embodiment 1 will be described. FIG. 8 is an external view of the temperature control garment according to Embodiment 1.

Temperature control garment 400 includes garment body 401, a plurality of first pockets 402, second pocket 403, and cable cover 404.

Garment body 401 is a jacket-like garment worn by the user on his or her upper body. Garment body 401 is a long-sleeved garment, but may be a short-sleeved or sleeveless garment. Garment body 401 may be a garment worn by the user on his or her lower body (such as pants). In the present specification, a garment refers to any component made of fabric that is worn by a user, and includes both a garment worn by a user on his or her upper body and a garment worn by a user on his or her lower body.

First pocket 402 is a pocket in which heating/cooling unit 200 is housed, and has a shape and size that fits heating/cooling unit 200, for example. Heating/cooling unit 200 is housed in first pocket 402 so that heat transfer plate 201 faces the user's body surface. The user's body surface (skin surface) is in contact with heat transfer plate 201 through the fabric of first pocket 402, and heating/cooling unit 200 can provide a warm or cool sensation to the user via heat transfer plate 201. In the example of FIG. 8, first pockets 402 are located at the collar, shoulders, sleeves, chest, near the waist (below the chest), and the lower backside of the neck (upper back) of temperature control garment 400, but may be located at other locations. The plurality of first pockets 402 may be arranged asymmetrically or symmetrically about a vertical axis. Temperature control garment 400 includes at least one first pocket 402.

The portion of first pocket 402 (or garment body 401) that opposes intake port 206a of heating/cooling unit 200 may be void of fabric or may be made of fabric that is more breathable than other portions. Stated differently, the portion of first pocket 402 (or garment body 401) that opposes intake port 206a may have a more breathable structure than other portions. This allows sufficiently cold outside air to be drawn into intake port 206a, making it easier to control heat transfer plate 201 of heating/cooling unit 200 to the desired temperature.

The portion of first pocket 402 (or garment body 401) that opposes exhaust port 206b of heating/cooling unit 200 may be void of fabric or may be made of fabric that is more breathable than other portions. Stated differently, the portion of first pocket 402 (or garment body 401) that opposes exhaust port 206b may have a more breathable structure than other portions. This allows the heated air to be discharged efficiently through exhaust port 206b to the outside of temperature control garment 400, making it easier to control heat transfer plate 201 of heating/cooling unit 200 to the desired temperature.

Second pocket 403 is a pocket in which external power supply 300 is housed. For example, second pocket 403 is shaped and sized to accommodate external power supply 300. It is not essential that second pocket 403 be provided in garment body 401; external power supply 300 may be housed in a pocket on a different garment than garment body 401. More specifically, external power supply 300 may be housed in a pants pocket. External power supply 300 may also be worn around the waist of the pants.

Cable cover 404 is a long tubular cover through which power cable 301 is passed. Cable cover 404 covers at least a portion of power cable 301. Cable cover 404 can regulate the position of power cable 301 and also make power cable 301 less visible from the outside. Garment body 401 is not required to include cable cover 404.

### Functional Configuration of Heating/Cooling Unit

Next, the functional configuration of heating/cooling unit 200 will be described. FIG. 9 is a block diagram illustrating the functional configuration of heating/cooling unit 200. FIG. 9 also illustrates mobile terminal 500 and wearable sensor 600.

As illustrated in FIG. 9, control circuit board 204 of heating/cooling unit 200 includes communication unit 204a, control unit 204b, storage unit 204c, and humidity sensor 204d. Although not illustrated, control circuit board 204 may include an angular rate sensor, an acceleration sensor, and/or a biometric sensor. A biometric sensor is a sensor that measures the user's biometric information, specifically, a heart rate sensor, a body temperature sensor, an electrocardiographic sensor, a myoelectric sensor, a blood pressure sensor, or a water quality sensor that measures the salt in the user's sweat.

Communication unit 204a receives control commands from mobile terminal 500. Communication unit 204a also receives biometric information from wearable sensor 600. Communication unit 204a, for example, is a wireless communication circuit and communicates with mobile terminal 500 based on a communication standard such as BLT (Bluetooth (registered trademark) Low Energy).

Control unit 204b controls thermoelectric conversion module 100 and blower fan 203 based on the control commands received by communication unit 204a. Control unit 204b is realized, for example, by a processor or microcomputer.

Storage unit 204c is a storage device which stores a computer program executed by a processor or microcomputer including control unit 204b. Storage unit 204c is realized, for example, by semiconductor memory.

Humidity sensor 204d is a sensor that measures the ambient humidity of heating/cooling unit 200. Humidity sensor 204d is realized, for example, by a humidity measuring element, such as a capacitive humidity-sensitive element or a variable resistance humidity-sensitive element. For example, humidity sensor 204d is provided on the surface of control circuit board 204 on the Z-axis negative direction side, in a region offset toward thermoelectric conversion module 100.

Mobile terminal 500 is an information terminal that functions as a user interface for a user to use heating/cooling unit 200 by communicating with communication unit 204a. The user can turn on, turn off, and switch between operating modes of heating/cooling unit 200 by operating mobile terminal 500. Mobile terminal 500 may also display the current temperature of heat transfer plate 201 (i.e., the measured temperature of second temperature detection element 107) included in heating/cooling unit 200. Mobile terminal 500 is a general-purpose mobile terminal, such as a smartphone or tablet device, but may be a dedicated terminal for heating/cooling unit 200. When mobile terminal 500 is a general-purpose mobile terminal, a dedicated application program is installed on mobile terminal 500.

Wearable sensor 600 is a sensor that measures the user's biometric information and transmits the measured biometric information to communication unit 204a. Biometric information includes, for example, the heart rate, the body temperature, an electrocardiogram (ECG), an electromyogram (EMG), and the amount of salt in sweat. Stated differently, wearable sensor 600 functions as at least one of the following sensors: a heart rate sensor, a body temperature sensor, an electrocardiographic sensor, a myoelectric sensor, a blood pressure sensor, and a water quality sensor. Wearable sensor 600 is, for example, a wristband sensor, but may be a headband sensor.

### Operation Example of Heating/Cooling Unit

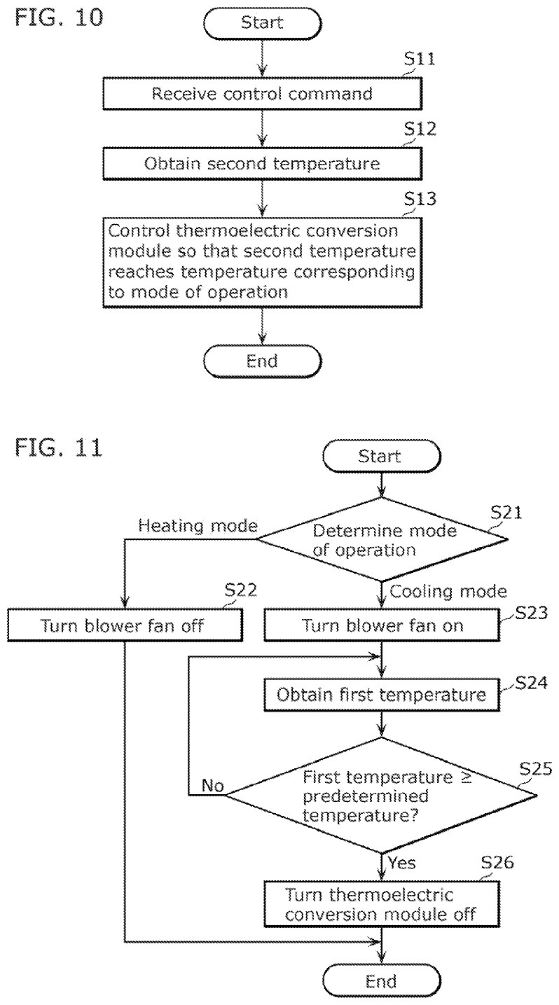

Next, an operation example of heating/cooling unit 200 will be given. FIG. 10 is a flowchart of an operation example of the heating/cooling unit.

Communication unit 204a of heating/cooling unit 200 receives a control command from mobile terminal 500 (S11). For example, the control command is transmitted from mobile terminal 500 to heating/cooling unit 200 by a user operating mobile terminal 500. The control command includes, for example, information indicating the mode of operation selected by the user. Modes of operation include a cooling mode, which is selected when the user wants heating/cooling unit 200 to provide a cool sensation, and a heating mode, which is selected when the user wants heating/cooling unit 200 to provide a warm sensation.

Next, control unit 204b obtains a second temperature measured by second temperature detection element 107 (S12). Stated differently, control unit 204b obtains the temperature of heat transfer plate 201. Control unit 204b can specifically obtain the resistance value (voltage and current) between the pair of second pads 101e as the second temperature.

Next, control unit 204b controls thermoelectric conversion module 100 so that the obtained second temperature reaches the temperature corresponding to the mode of operation indicated by the control command obtained in step S11 (S13). When the mode of operation indicated by the control command is the cooling mode, control unit 204b applies current in a first direction between the pair of power supply pads 101c so that the obtained second temperature reaches the temperature corresponding to the cooling mode (for example, 15° C.). In other words, control unit 204b cools heat transfer plate 201.

When the mode of operation indicated by the control command is the heating mode, control unit 204b applies current in a second direction opposite the first direction between the pair of power supply pads 101c so that the obtained second temperature reaches the temperature corresponding to the heating mode (for example, 40° C.). In other words, control unit 204b heats heat transfer plate 201. The direction in which the current flows between the pair of power supply pads 101c can be controlled by, for example, an H-bridge circuit (not illustrated in the drawings) mounted on control circuit board 204.

As described above, heating/cooling unit 200 can operate according to the user's desired mode of operation. Note that the user may select an operating intensity such as low, medium, or high in addition to the mode of operation through mobile terminal 500, and control unit 204b may control thermoelectric conversion module 100 so that the second temperature reaches the temperature determined by the mode of operation and the operating intensity.

The user may also specify a temperature setting via mobile terminal 500. In such cases, control unit 204b controls thermoelectric conversion module 100 so that the second temperature approaches the set temperature.

### Specific Operation Example of Heating/Cooling Unit

Next, a more specific operation example of heating/cooling unit 200 will be given. FIG. 11 is a flowchart of a specific operation example of heating/cooling unit 200. FIG. 11 illustrates a specific example of operations, other than supplying power to thermoelectric conversion module 100, that are performed in parallel with the operation in step S13 of FIG. 10.

First, control unit 204b determines the current mode of operation (S21). If the current mode of operation is the heating mode, the temperature of heat transfer plate 201 increases and the temperature of heat sink 202 decreases. Therefore, there is little need to operate blower fan 203. Accordingly, if control unit 204b determines that the current mode of operation is the heating mode (if the result of S21 is “heating mode”), control unit 204b turns off blower fan 203 and does not operate blower fan 203 (S22). This reduces power consumption and noise from the operation of blower fan 203.

If the current mode of operation is the cooling mode, the temperature of heat transfer plate 201 decreases and the temperature of heat sink 202 increases. Accordingly, if control unit 204b determines that the current mode of operation is the cooling mode (if the result of S21 is “cooling mode”), control unit 204b turns on blower fan 203 (S23) to enhance the heat dissipation of heat sink 202.

Here, if thermoelectric conversion module 100 is stopped by user instruction or other means after the temperature of heat sink 202 has increased, the temperature of heat transfer plate 201 and heat sink 202 may average out, causing heat transfer plate 201 to reach an unexpectedly high temperature. Therefore, in heating/cooling unit 200, a configuration is adopted to forcibly stop the operation of thermoelectric conversion module 100 once the temperature of heat sink 202 rises to a certain temperature.

Control unit 204b first obtains a first temperature measured by first temperature detection element 106 (S24). Stated differently, control unit 204b obtains the temperature of heat sink 202. Control unit 204b can specifically obtain the resistance value (voltage and current) between the pair of first pads 101d as the first temperature.

Next, control unit 204b determines whether the obtained first temperature is greater than or equal to a predetermined temperature (S25). The predetermined temperature is, for example, between 55° C. and 60° C., inclusive, but may be determined empirically or experimentally as appropriate. If the obtained first temperature is determined to be less than the predetermined temperature (No in S25), the obtainment of the first temperature is continued (S24) while blower fan 203 is continued to be operated. However, if control unit 204b determines that the obtained first temperature is greater than or equal to the predetermined temperature (Yes in S25), thermoelectric conversion module 100 is turned off (S26). Stated differently, control unit 204b stops supplying power to the pair of power supply pads 101c. This inhibits heat transfer plate 201 from reaching unexpectedly high temperatures.

In the example in FIG. 11, blower fan 203 rotates at a constant speed during operation in the cooling mode, but the speed of blower fan 203 may be controlled according to the first temperature measured by first temperature detection element 106. For example, control unit 204b increases the speed of blower fan 203 as the first temperature measured by first temperature detection element 106 increases. This allows for effective air cooling of heat sink 202. When the speed of blower fan 203 is controlled, a pulse width modulation (PWM) control circuit is mounted on control circuit board 204, and control unit 204b controls the speed of blower fan 203 via the PWM control circuit.

### Operation Example Using Biometric Information

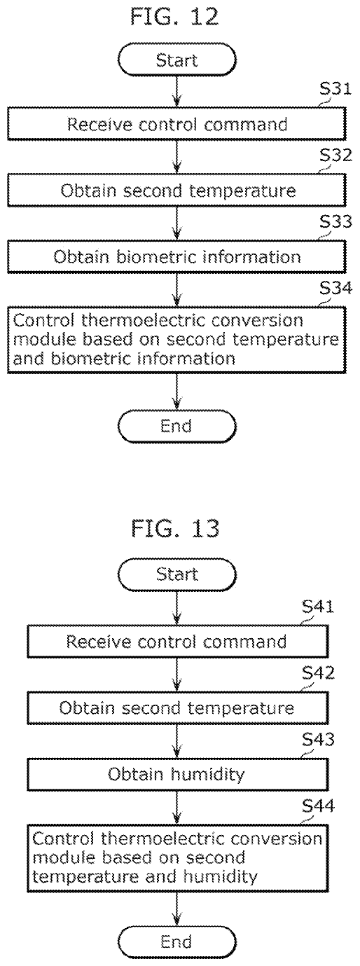

Heating/cooling unit 200 may operate based on the user's biometric information. FIG. 12 is a flowchart of an operation example of heating/cooling unit 200 based on biometric information.

Communication unit 204a of heating/cooling unit 200 receives a control command from mobile terminal 500 (S31). Next, control unit 204b obtains a second temperature measured by second temperature detection element 107 (S32). The processing of steps S31 and S32 is the same as that of steps S11 and S12.

Next, control unit 204b obtains biometric information (S33). If control circuit board 204 includes a biometric sensor, control unit 204b obtains biometric information from the biometric sensor on control circuit board 204. Control unit 204b may obtain biometric information from wearable sensor 600 via communication unit 204a.

Next, control unit 204b controls thermoelectric conversion module 100 based on the obtained second temperature and the obtained biometric information (S34). Control unit 204b controls thermoelectric conversion module 100 so as to reach the temperature corresponding to the mode of operation indicated by the control command, while also controlling thermoelectric conversion module 100 based on the biometric information.

For example, when the user is presumed to have a heart disease based on the electrocardiogram included in the biometric information, and when the user is presumed to have high blood pressure based on the blood pressure included in the biometric information, control unit 204b performs control to inhibit the amount of change in temperature per unit time more than for a user who is presumed to be healthy (i.e., performs control to inhibit sudden changes in temperature).

If the user is presumed to be cold based on the body temperature included in the biometric information, control unit 204b performs control to refrain from lowering the temperature more than for a user who is presumed to be healthy.

In this way, heating/cooling unit 200 can perform control according to the user's health condition based on the user's biometric information.

Note that control unit 204b may perform control to lower the temperature of heat transfer plate 201 when an increase in the user's body temperature is detected, or lower the temperature of heat transfer plate 201 when an increase in the user's heart rate is detected.

### Operation Example Using Humidity

Heating/cooling unit 200 may operate based on the humidity measured by humidity sensor 204d. FIG. 13 is a flowchart of an operation example of heating/cooling unit 200 based on humidity.

Communication unit 204a of heating/cooling unit 200 receives a control command from mobile terminal 500 (S41). Next, control unit 204b obtains a second temperature measured by second temperature detection element 107 (S42). The processing of steps S41 and S42 is the same as that of steps S11 and S12.

Next, control unit 204b obtains the humidity measured by humidity sensor 204d from humidity sensor 204d (S43).

Next, control unit 204b controls thermoelectric conversion module 100 based on the obtained second temperature and the obtained humidity (S44). Control unit 204b controls thermoelectric conversion module 100 so as to reach the temperature corresponding to the mode of operation indicated by the control command, while also controlling thermoelectric conversion module 100 based on the humidity.

If the humidity is high, it is presumed that the user is sweating. Accordingly, for example, control unit 204b performs control to lower the temperature when the obtained humidity is greater than or equal to the predetermined value more than when the obtained humidity is lower than the predetermined value.

Thus, heating/cooling unit 200 can control thermoelectric conversion module 100 based on the second temperature and the humidity.

As another example of an operation based on the humidity measured by humidity sensor 204d, control unit 204b may calculate a discomfort index based on the second temperature and humidity, and perform control to lower the temperature (second temperature) of heat transfer plate 201 until the calculated discomfort index is lower than a predetermined value (for example, 70).

### Variation 1 of Configuration of Heating/Cooling Unit

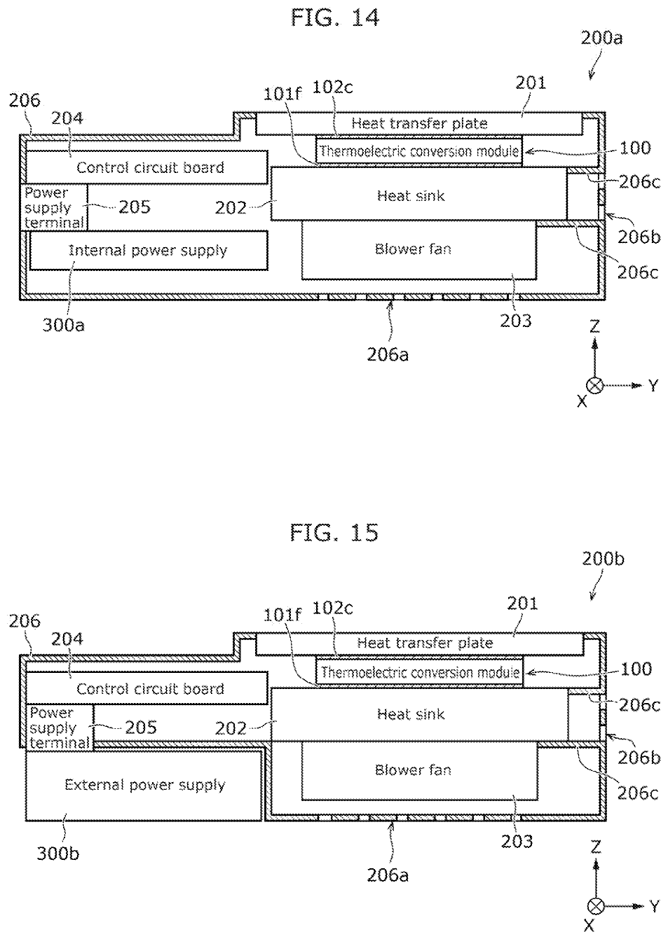

Next, Variation 1 of the configuration of heating/cooling unit 200 will be described. FIG. 14 is a schematic cross-sectional view of the internal structure of the heating/cooling unit according to Variation 1 of Embodiment 1.

Heating/cooling unit 200a according to Variation 1 includes thermoelectric conversion module 100, heat transfer plate 201, heat sink 202, blower fan 203, control circuit board 204, power supply terminal 205, case 206, and internal power supply 300a. The major differences between heating/cooling unit 200a and heating/cooling unit 200 are the inclusion of internal power supply 300a and the arrangement of blower fan 203.

Internal power supply 300a is located inside case 206 and is not removable by the user. Internal power supply 300a is located below control circuit board 204 in case 206. Internal power supply 300a includes a secondary cell, such as a lithium-ion cell, which can be charged when power supply terminal 205 is connected to a power adapter via a power cable.

In heating/cooling unit 200a, blower fan 203 is located below heat sink 202, and intake port 206a is located below blower fan 203 in case 206.

Thus, if heating/cooling unit 200a includes internal power supply 300a, there is no need to connect external power supply 300 to heating/cooling unit 200a. It is therefore not necessary to provide second pocket 403 and cable cover 404 in temperature control garment 400, simplifying the configuration of temperature control garment 400. Heating/cooling unit 200a can also be housed in first pocket 402 of temperature control garment 400 and operate in the same manner as heating/cooling unit 200.

### Variation 2 of Configuration of Heating/Cooling Unit

Next, Variation 2 of the configuration of heating/cooling unit 200 will be described. FIG. 15 is a schematic cross-sectional view of the internal structure of the heating/cooling unit according to Variation 2 of Embodiment 1.

Heating/cooling unit 200b according to Variation 2 includes thermoelectric conversion module 100, heat transfer plate 201, heat sink 202, blower fan 203, control circuit board 204, power supply terminal 205, case 206, and external power supply 300b. Heating/cooling unit 200b mainly differs from heating/cooling unit 200 in that it includes external power supply 300b.

External power supply 300b is removably mounted on the outside of case 206. In other words, unlike external power supply 300, which is separate from heating/cooling unit 200b, external power supply 300b is integrated with heating/cooling unit 200b.

External power supply 300b is mounted on the outer wall of case 206, below control circuit board 204. External power supply 300b is attached and detached by, for example, sliding it relative to case 206. External power supply 300b includes a secondary cell, such as a lithium-ion cell, for example, and is electrically connected to control circuit board 204, etc., inside case 206 via power supply terminal 205.

Thus, if heating/cooling unit 200b includes external power supply 300b, the user can replace external power supply 300b him or herself. If heating/cooling unit 200b includes an integrated external power supply 300b, there is no need to connect external power supply 300 to heating/cooling unit 200b. It is therefore not necessary to provide second pocket 403 and cable cover 404 in temperature control garment 400, simplifying the configuration of temperature control garment 400. Heating/cooling unit 200b can also be housed in first pocket 402 of temperature control garment 400 and operate in the same manner as heating/cooling unit 200.

### Embodiment 2

### Configuration of Thermoelectric Conversion Module

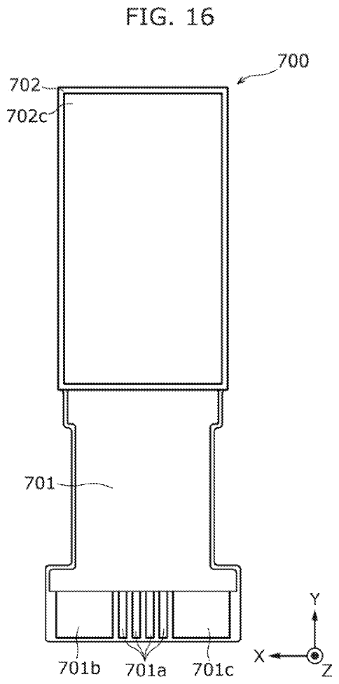

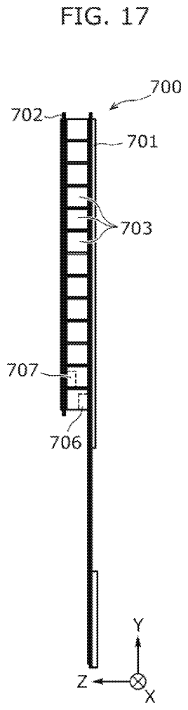

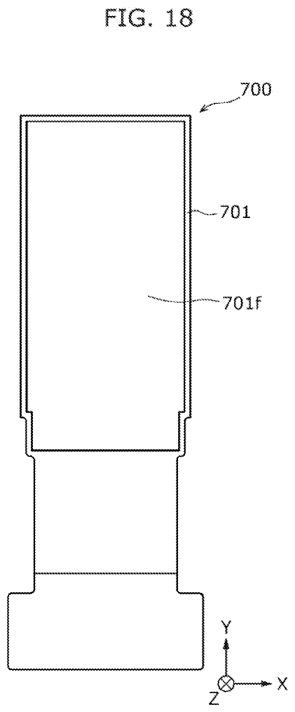

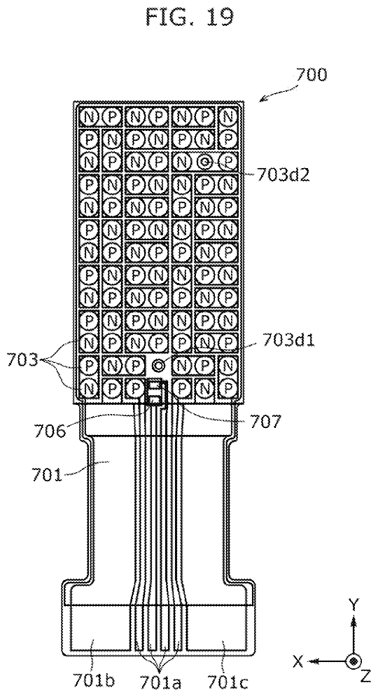

Hereinafter, the configuration of the thermoelectric conversion module according to Embodiment 2 will be described with reference to the drawings. FIG. 16 is a top view of the thermoelectric conversion module according to Embodiment 2. FIG. 17 is a side view of the thermoelectric conversion module according to Embodiment 2. FIG. 18 is a bottom view of the thermoelectric conversion module according to Embodiment 2. FIG. 19 is a see-through view of the arrangement of the thermoelectric element group in the thermoelectric conversion module according to Embodiment 2. In the following Embodiment 2, elements with the same names as those in Embodiment 1 are omitted from the detailed description as they have the same functions; the description will focus on the differences.

Thermoelectric conversion module 700 according to Embodiment 1 is a thermoelectric conversion module used in a heating/cooling unit to be described later. Thermoelectric conversion module 700 includes first substrate 701, second substrate 702, thermoelectric element group 703, first temperature detection element 706, and second temperature detection element 707. Thermoelectric element group 703 includes a plurality of first thermoelectric elements (labeled “N” in FIG. 19) and a plurality of second thermoelectric elements (labeled “P” in FIG. 19).

First substrate 701 is more elongated than first substrate 101, and heat dissipation pad 701f included in first substrate 701 is also more elongated than heat dissipation pad 101f. First lead line group 701a included in first substrate 701 is electrically connected to first temperature detection element 706 and second temperature detection element 707. Second lead line 701b and third lead line 701c included in first substrate 701 are electrically connected to thermoelectric element group 703.

Second substrate 702 is more elongated than second substrate 102, and heat transfer pad 702c included in second substrate 702 is also more elongated than heat transfer pad 102c.

In thermoelectric conversion module 700, first dummy electrode 703d1 and second dummy electrode 703d2 are provided mixed into thermoelectric element group 703. First dummy electrode 703d1 is the electrode through which current flows while thermoelectric conversion module 700 is operating. Second dummy electrode 703d2 is provided to improve the connection strength of first substrate 701 and second substrate 702; no current flows through second dummy electrode 703d2 while thermoelectric conversion module 700 is operating. First dummy electrode 703d1 and second dummy electrode 703d2 may also be provided in thermoelectric conversion module 100 according to Embodiment 1.

### Configuration of Heating/Cooling Unit

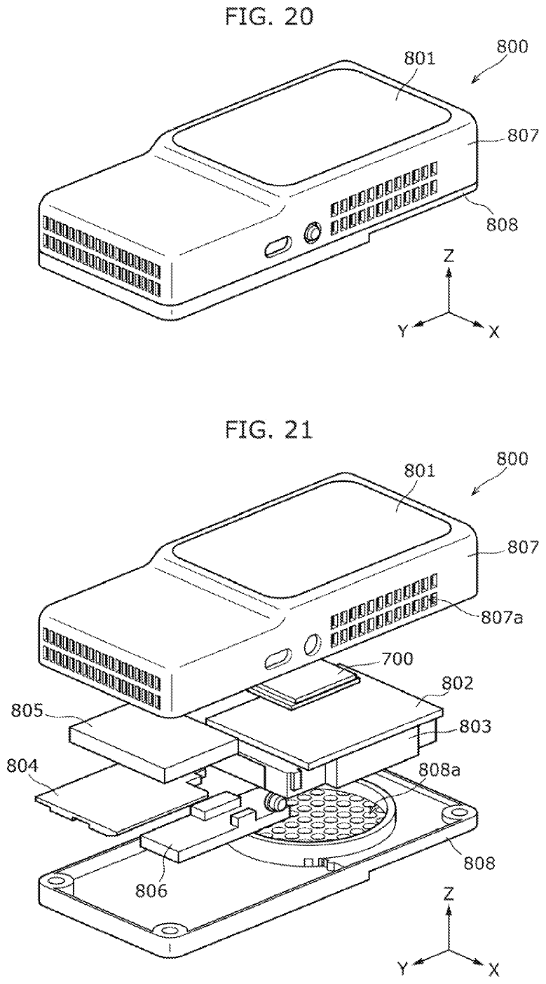

Next, the configuration of the heating/cooling unit according to Embodiment 2 will be described. FIG. 20 is an external perspective view of the heating/cooling unit according to Embodiment 2. FIG. 21 is an exploded perspective view of the heating/cooling unit according to Embodiment 2.

Heating/cooling unit 800 is a device that is housed in a pocket of temperature control garment 400 and provides a warm or cool sensation to the user wearing temperature control garment 400. Heating/cooling unit 800 includes thermoelectric conversion module 700, heat transfer plate 801, heat sink 802, first blower fan 803, control circuit board 804, internal power supply 805, charge/discharge circuit board 806, first case 807, and second case 808. First case 807 and second case 808 correspond to case 206 of heating/cooling unit 200.

The arrangement of components inside first case 807 and second case 808 of heating/cooling unit 800 is similar to that of heating/cooling unit 200a. Intake port 807a is provided in a side portion of first case 807. Intake port 807a is located to the side of thermoelectric conversion module 700 or first blower fan 803. Exhaust port 808a is provided in second case 808. Exhaust port 808a opposes first blower fan 803. When first blower fan 803 rotates, air outside first case 807 and second case 808 flows in through intake port 807a and air inside first case 807 and second case 808 flows out through exhaust port 808a.

Heating/cooling unit 800 includes internal power supply 805 and charge/discharge circuit board 806 inside first case 807 and second case 808.

Internal power supply 805 is located inside first case 807 and second case 808 and is not removable by the user. Internal power supply 805 is located below control circuit board 804 in first case 807 and second case 808. For example, internal power supply 805 includes a secondary cell, such as a lithium-ion cell, and is charged or discharged by a charge/discharge circuit mounted on charge/discharge circuit board 806.

Heating/cooling unit 800 described above can also be housed in first pocket 402 of temperature control garment 400 and operate in the same manner as heating/cooling unit 200.

### Variation 1 of Configuration of Heating/Cooling Unit

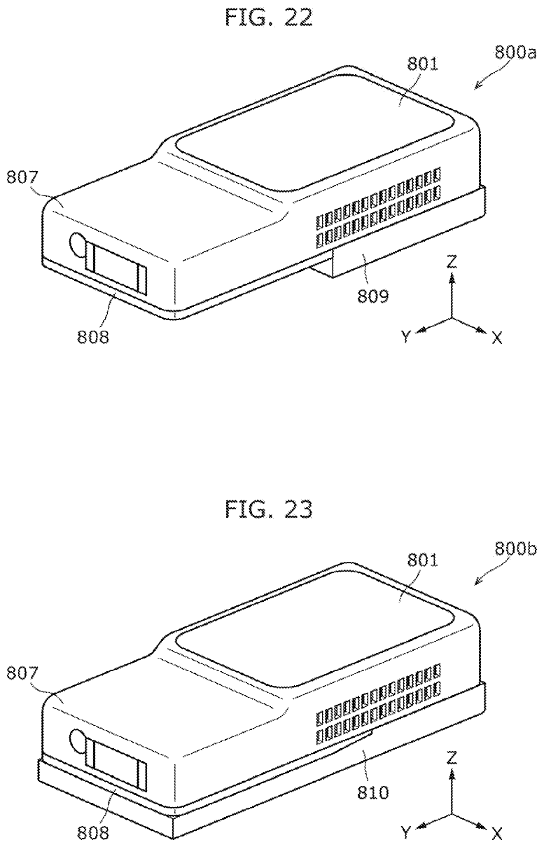

Next, Variation 1 of the configuration of heating/cooling unit 800 will be described. FIG. 22 is an external perspective view of the heating/cooling unit according to Variation 1 of Embodiment 2.

Heating/cooling unit 800a according to Variation 1 has a configuration equivalent to heating/cooling unit 800 additionally including second blower fan 809. Second blower fan 809 is provided outside second case 808, opposing exhaust port 808a.

Heating/cooling unit 800a functions as a small fan using second blower fan 809. For example, air with a lower temperature than the temperature of the air surrounding heating/cooling unit 800a can be blown from second blower fan 809 by passing electrical current through thermoelectric conversion module 700 so that the heat sink 802 side is cooled. The user can, for example, get a comfortable cooling sensation by applying cool air to their face or forehead in summer. Heating/cooling unit 800a is effective in inhibiting heat stroke. Moreover, air with a higher temperature than the temperature of the air surrounding heating/cooling unit 800a can be blown from second blower fan 809 by passing electrical current through thermoelectric conversion module 700 so that the heat sink 802 side is heated.

As with control circuit board 204 described in Embodiment 1, a biometric sensor and a humidity sensor may be provided on control circuit board 804. In such cases, heating/cooling unit 800a can control the temperature of thermoelectric conversion module 700 and the speed of second blower fan 809 based on biometric information such as the heart rate, the body temperature, an electrocardiogram, an electromyogram, or the amount of salt in sweat, or based on the humidity. The user can set the temperature or the like according to their daily health condition. Data such as an electrocardiogram or an electromyogram may be measured and obtained by the user at a hospital, and such data may be stored in user's mobile terminal 500 and utilized through a communication connection with heating/cooling unit 800a.

A protective case (not illustrated in the drawings) may be attached to heating/cooling unit 800a. The protective case may have hardware for attaching heating/cooling unit 800a, or holes for straps.

Heating/cooling unit 800a may be equipped with a display unit that shows, for example, the remaining charge of the secondary cell, the mode of operation (cooling mode or heating mode), and the temperature setting. In such cases, the protective case may include a hole for visibility of the display unit, in a position that corresponds to the display unit.

The silhouette of heating/cooling unit 800a is not limited to an approximate cuboid shape. The silhouette of heating/cooling unit 800a may be round or a shape similar to a mouse for operating a personal computer. These shapes have the effect of making it easier for the user to hold heating/cooling unit 800a and thus to maintain a posture in which cold air is blown to the face or other parts of the body. In addition, the user can hold heating/cooling unit 800a away from his or her body with his or her hand, which contributes to avoiding tedium and discomfort associated with controlling the temperature of one part of the body for an extended period of time.

Heating/cooling unit 800a may have a waterproof structure to protect against external moisture from sweat and rain. For example, the shape and size of each hole in heating/cooling unit 800a may be smaller than a drop of water. Intake port 807a and exhaust port 808a of heating/cooling unit 800a may be provided with a mesh structure. The mesh structure may be provided on the outside of first case 807 and second case 808, or on the inside of first case 807 and second case 808.

### Variation 2 of Configuration of Heating/Cooling Unit

Next, Variation 2 of the configuration of heating/cooling unit 800 will be described. FIG. 23 is an external perspective view of the heating/cooling unit according to Variation 2 of Embodiment 2.

Heating/cooling unit 800b according to Variation 2 has a configuration equivalent to heating/cooling unit 800 additionally including external power supply 810. Note that heating/cooling unit 800b may have a configuration equivalent to heating/cooling unit 800a additionally including external power supply 810.

External power supply 810 specifically includes a secondary cell and a secondary cell holding case, and is removably attached to second case 808. External power supply 810 is attached and detached by, for example, sliding it relative to case 206. In other words, external power supply 810 is integrated with heating/cooling unit 800b.

Thus, if heating/cooling unit 800b includes external power supply 810, the user can replace external power supply 810 him or herself. Internal power supply 805 may be omitted in heating/cooling unit 800b. Heating/cooling unit 800b can also be housed in first pocket 402 of temperature control garment 400 and operate in the same manner as heating/cooling unit 200.

### CONCLUSION

As described above, thermoelectric conversion module 100 includes: first substrate 101 and second substrate 102 that positionally oppose each other; thermoelectric element group 103 that is located between first substrate 101 and second substrate 102 and is connected to first substrate 101 and second substrate 102; first temperature detection dement 106 that is located between first substrate 101 and second substrate 102 and is connected to first substrate 101; and second temperature detection dement 107 that is located between first substrate 101 and second substrate 102 and is connected to second substrate 102.

As a result of thermoelectric conversion module 100 including a temperature detection element connected to first substrate 101 and a temperature detection element connected to second substrate 102, thermoelectric conversion module 100 can be adapted to a greater variety of controls than a thermoelectric conversion module including only one temperature detection element. For example, thermoelectric conversion module 100 can be easily adapted to applications that require temperature detection or temperature control of each of first substrate 101 and second substrate 102.

For example, first substrate 101 includes first region 111 that overlaps second substrate 102 in plan view and second region 112 that is adjacent to first region 111 and does not overlap second substrate 102 in plan view. A pad is provided in second region 112 for electrically connecting thermoelectric conversion module 100 to an external circuit (for example, the control circuit provided on control circuit board 204). First temperature detection element 106 and second temperature detection element 107 are located in sub-region 111a of first region 111 that is closer to second region 112 in plan view.

This shortens the distance from first temperature detection element 106 to the pair of first pads 101d, whereby the wiring connecting first temperature detection element 106 to the pair of first pads 101d can be shortened and the wiring routing can be simplified. Moreover, the wiring connecting second temperature detection element 107 and the pair of second pads 101e can be shortened and the wiring routing can be simplified.

For example, in plan view, thermoelectric element group 103 is arranged in a matrix along the Y-axis direction (one example of the first direction) in which first region 111 and second region 112 are aligned and the X-axis direction (one example of the second direction) intersecting the Y-axis direction. First thermoelectric element column 103a including a portion of thermoelectric elements in thermoelectric element group 103 is provided in sub-region 111a of first region 111 that is closer to second region 112. First thermoelectric element column 103a is aligned along the X-axis direction (one example of the second direction) and located closest to second region 112 among thermoelectric element columns. Second thermoelectric element column 103b including a portion of other thermoelectric elements in thermoelectric element group 103 is provided in sub-region 111a of first region 111 that is closer to second region 112. Second thermoelectric element column 103b is aligned along the X-axis direction and located adjacent to first thermoelectric element column 103a in the Y-axis direction. In plan view, first temperature detection element 106 and second temperature detection element 107 are located closer to second region 112 than second thermoelectric element column 103b is.

With this, the wiring connecting first temperature detection element 106 and the pair of first pads 101d can be further shortened and the wiring routing can be further simplified. Moreover, the wiring connecting second temperature detection element 107 and the pair of second pads 101e can be further shortened and the wiring routing can be further simplified.

For example, a pair of power supply pads 101c and a plurality of pads (the pair of first pads 101d and the pair of second pads 101e) are provided in second region 112. The pair of power supply pads 101c are for supplying power to thermoelectric conversion module 100. The plurality of pads are located between the pair of power supply pads 101c in plan view and are for measuring a resistance value of first temperature detection element 106 and a resistance value of second temperature detection element 107. When first substrate 101 is divided into third region 113 and fourth region 114 in the X-axis direction intersecting the Y-axis direction in which first region 111 and second region 112 are aligned, first temperature detection element 106 and second temperature detection element 107 are located in fourth region 114 in plan view. Third region 113 is a region in which the pair of power supply pads 101c are provided. Fourth region 114 is a region in which the plurality of pads are provided and is adjacent to third region 113 in the X-axis direction.

With this, the wiring connecting first temperature detection element 106 and the pair of first pads 101d can be shortened and the wiring routing can be simplified. Moreover, the wiring connecting second temperature detection element 107 and the pair of second pads 101e can be shortened and the wiring routing can be simplified.

For example, in plan view, first temperature detection element 106 and second temperature detection element 107 are located in central part 115 of second substrate 102.

This improves the measurement accuracy of the temperature of heat dissipation pad 101f and heat transfer pad 102c.

For example, heat dissipation pad 101f is provided on the surface of first substrate 101 opposite to the surface of first substrate 101 that faces second substrate 102, and heat transfer pad 102c is provided on the surface of second substrate 102 opposite to the surface of second substrate 102 that faces first substrate 101. In plan view, second temperature detection element 107 is located closer to intersection point C of diagonals of second substrate 102 than first temperature detection element 106 is.

This achieves a thermoelectric conversion module 100 in which the measurement accuracy of the temperature of heat transfer pad 102c is prioritized over the measurement accuracy of the temperature of heat dissipation pad 101f.

For example, in plan view, first temperature detection element 106 at least partially overlaps second temperature detection element 107.

This reduces the difference in temperature measurement conditions between first temperature detection element 106 and second temperature detection element 107.

For example, in plan view, first temperature detection element 106 does not overlap second temperature detection element 107.

This increases the degree of freedom in the placement of first temperature detection element 106 and second temperature detection element 107.

For example, in plan view, the distance between first temperature detection element 106 and second temperature detection element 107 is less than or equal to the maximum width of first temperature detection element 106 or the maximum width of second temperature detection element 107.

This increases the degree of freedom in the placement of first temperature detection element 106 and second temperature detection element 107 and reduces the difference in temperature measurement conditions between first temperature detection element 106 and second temperature detection element 107.

Heating/cooling unit 200 includes: thermoelectric conversion module 100; heat transfer plate 201 disposed on the surface of second substrate 102 opposite to the surface of second substrate 102 that faces first substrate 101; heat sink 202 disposed on the surface of first substrate 101 opposite to the surface of first substrate 101 that faces second substrate 102; blower fan 203 that blows air toward heat sink 202; control circuit board 204 on which a control circuit that controls thermoelectric conversion module 100 and blower fan 203 is mounted; and case 206 that houses thermoelectric conversion module 100, heat transfer plate 201, heat sink 202, blower fan 203, and control circuit board 204. Heat transfer plate 201 is at least partially exposed to the outside of case 206 through an opening in case 206.

With this, heating/cooling unit 200 can control thermoelectric conversion module 100 and blower fan 203 using both the measured temperature of first temperature detection element 106 and the measured temperature of second temperature detection element 107.

Heating/cooling unit 200a further includes a power supply (for example, internal power supply 300a) that is provided inside case 206 and supplies power to control circuit board 204.

Thus, if heating/cooling unit 200a includes a power supply inside case 206, there is no need to connect external power supply 300 to heating/cooling unit 200a. It is therefore not necessary to provide second pocket 403 and cable cover 404 in temperature control garment 400, simplifying the configuration of temperature control garment 400.

Heating/cooling unit 200b further includes a power supply (for example, external power supply 300b) that is provided outside case 206, is configured to be attached to case 206, and supplies power to control circuit board 204.

Thus, if heating/cooling unit 200b includes external power supply 300b, the user can replace external power supply 300b him or herself. Moreover, there is no need to connect external power supply 300 to heating/cooling unit 200b. It is therefore not necessary to provide second pocket 403 and cable cover 404 in temperature control garment 400, simplifying the configuration of temperature control garment 400.

Heating/cooling unit 200 further includes a power supply (for example, external power supply 300) that is provided outside case 206, in a location apart from case 206, and supplies power to control circuit board 204.

This makes it easier to reduce the weight and size of heating/cooling unit 200 since heating/cooling unit 200 does not require an internal power supply.

Intake port 206a is provided in case 206, in a portion opposing blower fan 203, and exhaust port 206b is provided in case 206, in a portion located to a side of thermoelectric conversion module 100 or blower fan 203.

This allows heating/cooling unit 200 to air cool the inside of case 206.

Exhaust port 206b is provided in the portion of case 206 located to the side of thermoelectric conversion module 100 or blower fan 203, on the side of case 206 opposite to the side of case 206 on which heat transfer plate 201 is provided.

This prevents air discharged from exhaust port 206b from hitting the user's body surface.

An axis of an opening defined by intake port 206a is inclined relative to the surface of case 206 in which intake port 206a is provided.

This makes it possible to secure space for air intake between heating/cooling unit 200 and the garment. Moreover, this will have the effect of inhibiting foreign objects such as hair, dust, or garment fibers from entering case 206 through intake port 206a.

The surface of case 206 in which intake port 206a is provided has a curvature that protrudes toward the outside of case 206, and intake port 206a is provided in an area away from peak portion 206d of the curvature.

When heating/cooling unit 200 is housed in a pocket of a garment, this allows space for air intake between heating/cooling unit 200 and the garment. Stated differently, it is possible to inhibit the fabric of the garment from completely covering intake port 206a.

A portion of case 206 that is adjacent to heat transfer plate 201 is recessed (for example, recessed portion 206e) toward the inside of case 206 more so than heat transfer plate 201, and control circuit board 204 opposes the recessed portion inside case 206.

This inhibits the heated portion of control circuit board 204 from coming close to the user's body surface and from coming into contact with the user's body surface. Stated differently, heating/cooling unit 200 is inhibited from providing a warming sensation to the user that is not by design.

The silhouette of case 206 has a longitudinal direction and a lateral direction in plan view, and an end portion in the longitudinal direction of case 206 (for example, the end portion in the Y-axis negative direction) has a tapered shape.

This has the effect of making it easier to place heating/cooling unit 200 in a pocket of the garment.

Temperature control garment 400 includes: heating/cooling unit 200; garment body 401; and first pocket 402 that is provided in garment body 401 and houses heating/cooling unit 200.

With this, temperature control garment 400 can provide a warm or cold sensation to the user via heating/cooling unit 200.

For example, the portion of first pocket 402 that opposes intake port 206a has a more breathable structure than other portions (for example, garment body 401).

This allows heating/cooling unit 200 to draw air in more efficiently.

For example, the portion of first pocket 402 that opposes exhaust port 206b has a more breathable structure than other portions (for example, garment body 401).

This allows heating/cooling unit 200 to discharge air more efficiently.

For example, temperature control garment 400 further includes second pocket 403 that is provided in garment body 401 and houses external power supply 300 that supplies power to heating/cooling unit 200.

This allows temperature control garment 400 to house external power supply 300.

For example, temperature control garment 400 further includes cable cover 404 that is provided in garment body 401 and covers at least part of power cable 301 that connects external power supply 300 and heating/cooling unit 200.

This allows temperature control garment 400 to cover power cable 301, thereby inhibiting the appearance of temperature control garment 400 from being compromised.

### Other Embodiments

Although the present disclosure has been described by way of embodiments, the present disclosure is not limited to the above embodiments.

For example, general and specific aspects may be realized using a system, a device or apparatus, a method, an integrated circuit, a computer program, or a computer-readable recording medium such as a CD-ROM, or any combination thereof. For example, the present disclosure may be realized as a control method for the thermoelectric conversion module, or as a program for causing a computer to execute such a control method. The present disclosure may also be realized as a non-transitory computer-readable recording medium on which such a program is recorded.

The present disclosure may also be realized as an application program to be installed on a mobile terminal for controlling the heating/cooling unit, or as a non-transitory computer-readable recording medium on which such an application program is recorded.

Additionally, embodiments arrived at by those skilled in the art making modifications to the above embodiments, as well as embodiments arrived at by combining various elements and functions described in the above embodiments without materially departing from the novel teachings and advantages of the present teachings, are intended to be included within the scope of the present disclosure.

### INDUSTRIAL APPLICABILITY

The thermoelectric conversion module according to the present disclosure can be applied to a variety of controls and can be used in a heating/cooling unit that provides a warm or cold sensation to the user.

1. A thermoelectric conversion module comprising:
a first substrate and a second substrate that positionally oppose each other;
a thermoelectric element group that is located between the first substrate and the second substrate and is connected to the first substrate and the second substrate;
a first temperature detection element that is located between the first substrate and the second substrate and is connected to the first substrate; and
a second temperature detection element that is located between the first substrate and the second substrate and is connected to the second substrate.

2. The thermoelectric conversion module according to claim 1, wherein
the first substrate includes a first region that overlaps the second substrate in plan view and a second region that is adjacent to the first region and does not overlap the second substrate in plan view,
a pad is provided in the second region for electrically connecting the thermoelectric conversion module to an external circuit, and
the first temperature detection element and the second temperature detection element are located in a sub-region of the first region that is closer to the second region in plan view.

3. The thermoelectric conversion module according to claim 2, wherein
in plan view, the thermoelectric element group is arranged in a matrix along a first direction in which the first region and the second region are aligned and a second direction intersecting the first direction,
a first thermoelectric element column including a portion of thermoelectric elements in the thermoelectric element group is provided in the sub-region, the first thermoelectric element column being aligned along the second direction and located closest to the second region among thermoelectric element columns,
a second thermoelectric element column including a portion of other thermoelectric elements in the thermoelectric element group is provided in the sub-region, the second thermoelectric element column being aligned along the second direction and located adjacent to the first thermoelectric element column in the first direction, and
in plan view, the first temperature detection element and the second temperature detection element are located closer to the second region than the second thermoelectric element column is.

4. The thermoelectric conversion module according to claim 2, wherein
a pair of power supply pads and a plurality of pads are provided in the second region, the pair of power supply pads being for supplying power to the thermoelectric conversion module, the plurality of pads being located between the pair of power supply pads in plan view and being for measuring a resistance value of the first temperature detection element and a resistance value of the second temperature detection element, and
when the first substrate is divided into a third region and a fourth region in a second direction intersecting a first direction in which the first region and the second region are aligned, the first temperature detection element and the second temperature detection element are located in the fourth region in plan view, the third region being a region in which the pair of power supply pads are provided, the fourth region being a region in which the plurality of pads are provided and being adjacent to the third region in the second direction.

5. The thermoelectric conversion module according to claim 1, wherein
in plan view, the first temperature detection element and the second temperature detection element are located in a central part of the second substrate.

6. The thermoelectric conversion module according to claim 1, wherein
a heat dissipation pad is provided on a surface of the first substrate opposite to a surface of the first substrate that faces the second substrate,
a heat transfer pad is provided on a surface of the second substrate opposite to a surface of the second substrate that faces the first substrate, and
in plan view, the second temperature detection element is located closer to an intersection point of diagonals of the second substrate than the first temperature detection element is.

7. The thermoelectric conversion module according to claim 1, wherein
in plan view, the first temperature detection element at least partially overlaps the second temperature detection element.

8. The thermoelectric conversion module according to claim 1, wherein
in plan view, the first temperature detection element does not overlap the second temperature detection element.

9. The thermoelectric conversion module according to claim 8, wherein
in plan view, a distance between the first temperature detection element and the second temperature detection element is less than or equal to a maximum width of the first temperature detection element or a maximum width of the second temperature detection element.

10. A heating/cooling unit comprising:
the thermoelectric conversion module according to claim 1;
a heat transfer plate disposed on a surface of the second substrate opposite to a surface of the second substrate that faces the first substrate;
a heat sink disposed on a surface of the first substrate opposite to a surface of the first substrate that faces the second substrate;
a blower fan that blows air toward the heat sink;
a control circuit board on which a control circuit that controls the thermoelectric conversion module and the blower fan is mounted; and
a case that houses the thermoelectric conversion module, the heat transfer plate, the heat sink, the blower fan, and the control circuit board, wherein
the heat transfer plate is at least partially exposed to an outside of the case through an opening in the case.

11. The heating/cooling unit according to claim 10, further comprising:
a power supply that is provided inside the case and supplies power to the control circuit board.

12. The heating/cooling unit according to claim 10, further comprising:
a power supply that is provided outside the case, is configured to be attached to the case, and supplies power to the control circuit board.

13. The heating/cooling unit according to claim 10, further comprising:
a power supply that is provided outside the case, in a location apart from the case, and supplies power to the control circuit board.

14. The heating/cooling unit according to claim 11, wherein
an intake port is provided in the case, in a portion opposing the blower fan, and
an exhaust port is provided in the case, in a portion located to a side of the thermoelectric conversion module or the blower fan.

15. The heating/cooling unit according to claim 14, wherein the exhaust port is provided in the portion of the case located to the side of the thermoelectric conversion module or the blower fan, on a side of the case opposite to a side of the case on which the heat transfer plate is provided.

16. The heating/cooling unit according to claim 14, wherein
an axis of an opening defined by the intake port is inclined relative to a surface of the case in which the intake port is provided.

17. The heating/cooling unit according to claim 14, wherein
a surface of the case in which the intake port is provided has a curvature that protrudes toward an outside of the case, and
the intake port is provided in an area away from a peak portion of the curvature.

18. The heating/cooling unit according to claim 10, wherein
a portion of the case that is adjacent to the heat transfer plate is recessed toward an inside of the case more so than the heat transfer plate, and
the control circuit board opposes the recessed portion inside the case.

19. The heating/cooling unit according to claim 10, wherein
a silhouette of the case has a longitudinal direction and a lateral direction in plan view, and
an end portion in the longitudinal direction of the case has a tapered shape.

20. A temperature control garment comprising:
the heating/cooling unit according to claim 10;
a garment body; and
a first pocket that is provided in the garment body and houses the heating/cooling unit.

21. A temperature control garment comprising:
the heating/cooling unit according to claim 14;
a garment body; and
a first pocket that is provided in the garment body and houses the heating/cooling unit, wherein
a portion of the first pocket that opposes the intake port has a more breathable structure than other portions.

22. A temperature control garment comprising:
the heating/cooling unit according to claim 14;
a garment body; and
a first pocket that is provided in the garment body and houses the heating/cooling unit, wherein
a portion of the first pocket that opposes the exhaust port has a more breathable structure than other portions.

23. The temperature control garment according to claim 20, further comprising:
a second pocket that is provided in the garment body and houses a power supply that supplies power to the heating/cooling unit.

24. The temperature control garment according to claim 23, further comprising:
a cover that is provided in the garment body and covers at least part of a cable that connects the power supply and the heating/cooling unit.
